(19) United States
(12) Patent Application Publication
(10) Pub. No.: US 2016/0116368 A1
(43) Pub. Date: Apr. 28, 2016

(54) METHOD FOR APPROXIMATING REMAINING LIFETIME OF ACTIVE DEVICES

(71) Applicant: Samtec, Inc., New Albany, IN (US)

(72) Inventors: Joshua R. CORNELIUS, Los Altos, CA (US); Eric Jean ZBINDEN, Sunnyvale, CA (US); Jean-Marc Andre VERDIELL, Atherton, CA (US); William J. KOZLOVSKY, Sunnyvale, CA (US); Kevin BURT, San Jose, CA (US); Thomas Benjamin TROXELL, San Jose, CA (US); Lesly LEROY, Milpitas, CA (US); David A. LANGSAM, Sunnyvale, CA (US); Andrew John BAXTER, Berkeley, CA (US)

(21) Appl. No.: 14/921,061

(22) Filed: Oct. 23, 2015

Related U.S. Application Data
(60) Provisional application No. 62/067,570, filed on Oct. 23, 2014.

(51) Int. Cl. G01M 11/00; G11C 16/02

(52) U.S. Cl. CPC G01M 11/30; G11C 16/02

(57) ABSTRACT

A method of calculating an effective age of an active optical cable including a fiber optic cable, at least one optical transducer, a first memory, and a second memory includes, during regular intervals that are divided into regular subintervals and after each of the regular subintervals, sensing an operational parameter of the active optical cable and recording in the second memory a value corresponding to a sensed operational parameter; after each of the regular intervals, storing in the first memory the values recorded in the second memory; and calculating the effective age of the active optical cable based on the values stored in the first memory.

### BACKGROUND OF THE INVENTION

1. Field of the Invention

The present invention relates to a method of measuring and recording temperature data for an active device and to a method of approximating the remaining lifetime of active devices. More specifically, the present invention relates a method of measuring and recording temperature data of an active device using memory with limited ability to be written to and of limited capacity, and to a method of approximating the remaining lifetime of an active device based on its temperature history.

2. Description of the Related Art

The lifetime, i.e. the time before a failure occurs, of any active device depends on the operating environment of the active device, including temperature, humidity, etc. The mean time to failure (MTTF) is the average predicted operating time of a device before failure occurs. The MTTF of an active device also depends on the operating environment of the active device. Manufacturers typically provide MTTF for a given operating condition (temperature, humidity, current, etc.). However, the operating temperature of active devices can vary greatly depending on the application.

An example of an active device is a vertical-cavity surface-emitting laser (VCSEL). VCSELs are semiconductor optical sources that emit coherent light and are commonly integrated into systems in fiber-optic applications. One such system is an active optical cable (AOCs), which is a fiber optic cable that includes electrical-to-optical and/or optical-to-electrical converters called optical transducers. VCSELs tend to wear out more rapidly at elevated temperatures and are the most likely source of failure in AOCs. VCSEL can refer to either a single laser or an array of lasers on a single die (i.e., a VCSEL array).

A problem with active devices is that it is not known when they are going to fail. Ideally, the conditions of the operating environment of the active device are continuously monitored and recorded. However, this is not always possible. For example, an AOC cannot continuously monitor and record temperature because the AOC's non-volatile memory can only be written to a limited number of times. If an electrically erasable programmable read-only memory (EEPROM) semiconductor device is used as the AOC's memory, such memory has a limited number of write cycles. As an example, certain EEPROMs manufactured by ATMEL (San Jose, Calif.) are rated at 30,000 write cycles at 85° C. operating temperature before failure.

### SUMMARY OF THE INVENTION

To overcome the problems described above, preferred embodiments of the present invention provide a method of measuring and recording temperature data of an active device using memory with limited ability to be written to and limited capacity, and provide a lifetime-approximation method using the temperature data to approximate the age of the active data.

In a preferred embodiment of the present invention, an AOC includes a VCSEL, volatile and non-volatile memory elements, a processor, and a sensor. The sensor provides information regarding an operational parameter impacting active device aging. The sensor is monitored at regular subintervals by the processor, and the resultant information is stored in volatile memory. Information stored in the volatile memory is transferred by the processor and written to the non-volatile memory at regular intervals, with the length of an interval being longer than the length of a subinterval so as to reduce the number of write cycles of the non-volatile memory. The information stored in the non-volatile memory is used to determine the effective age of the active device.

A preferred embodiment of the present invention provides an active optical cable that includes a fiber optic cable, at least one optical transducer, a first memory, a second memory, a sensor that senses an operational parameter of the active optical cable, and a processor connected to the least one optical transducer, the first memory, the second memory, and the sensor. The processor, during regular intervals that are divided into regular subintervals and after each of the regular subintervals, records in the second memory a value corresponding to a sensed operational parameter and, after each of the regular intervals, stores in the first memory the values recorded in the second memory.

The regular intervals and the regular subintervals are preferably based on an expected number of writes to the first memory and an expected lifetime of the active optical cable. The operational parameter is preferably temperature.

Preferably, the second memory includes bins, and each of the bins corresponds to a range of values of the sensed operational parameter. The processor preferably records in the second memory the value corresponding to the sensed operational parameter by incrementing by one a bin value of a bin that corresponds to the range of values of the sensed operational parameter that includes the value of the sensed operational parameter. The first memory preferably includes bins corresponding to the bins in the second memory. The processor preferably stores in the first memory the values recorded in the second memory by adding a bin value of each of the bins in the second memory to a corresponding bin value previously stored in corresponding bins in the first memory. The processor preferably calculates an effective age of the active optical cable based on the bin values of the bins stored in the first memory. The processor preferably calculates the effective age based solely on the bin values of the bins stored in the first memory. The processor preferably provides an indicator signal if the effective age is above a threshold value. Preferably, the operational parameter is temperature; each of the bins represents a range of temperatures; and the processor calculates an effective age of the active optical cable t_{effective} using the formula:

$${t}_{effective} = \frac{m}{60} {\sum }_{n = 1}^{b} {A}_{Fn} {N}_{n} [ hours ]$$

$$where$$

$${A}_{Fn} = {e}^{[ \frac{- {E}_{A}}{{k}_{B}} ( \frac{1}{{T}_{n}} - \frac{1}{{T}_{R}} ) ]} ,$$

m is a time of a regular subinterval in minutes, b is a number of bins, Nₙ is a value stored in bin n, E_{A} is an activation energy, k_{B} is Boltzmann's constant, Tₙ is a bin temperature, and T_{R} is a reference temperature.

After each of the regular intervals, the processor preferably resets the values stored in the second memory. The processor preferably calculates an effective age of the active optical cable based on the values stored in the first memory. The first memory preferably is a non-volatile memory, and the second memory preferably is a volatile memory. The first memory preferably is an EEPROM.

A preferred embodiment of the present invention provides a method of calculating an effective age of an active optical cable including a fiber optic cable, at least one optical transducer, a first memory, and a second memory that includes, during regular intervals that are divided into regular subintervals and after each of the regular subintervals, sensing an operational parameter of the active optical cable and recording in the second memory a value corresponding to a sensed operational parameter; after each of the regular intervals, storing in the first memory the values recorded in the second memory; and calculating the effective age of the active optical cable based on the values stored in the first memory.

The regular intervals and the regular subintervals preferably are based on an expected number of writes to the first memory and an expected lifetime of the active optical cable. The operational parameter preferably is temperature.

Preferably, the second memory includes bins, and each of the bins corresponds to a range of values of the sensed operational parameter. The recording in the second memory the value corresponding to the sensed operational parameter preferably includes incrementing by one a bin value of a bin that corresponds to the range of values of the sensed operational parameter that includes the value of the sensed operational parameter. The first memory preferably includes bins corresponding to the bins in the second memory. The storing in the first memory the values recorded in the second memory preferably includes adding a bin value of each of the bins in the second memory to a corresponding bin value previously stored in corresponding bins in the first memory. Calculating the effective age of the active optical cable is preferably based on the bin values of the bins stored in the first memory. Calculating the effective age is preferably based solely on the bin values of the bins stored in the first memory. The method further preferably includes providing an indicator signal if the effective age is above a threshold value. Preferably, the operational parameter is temperature; each of the bins represents a range of temperatures; and the calculating the effective age of the active optical cable includes using the formula:

$${t}_{effective} = \frac{m}{60} {\sum }_{n = 1}^{b} {A}_{Fn} {N}_{n} [ hours ]$$

$$where$$

$${A}_{Fn} = {e}^{[ \frac{- {E}_{A}}{{k}_{B}} ( \frac{1}{{T}_{n}} - \frac{1}{{T}_{R}} ) ]} ,$$

t_{effective} is an effective age of the active optical cable, m is a time of a regular subinterval in minutes, b is a number of bins, Nₙ is a value stored in bin n, E_{A} is an activation energy, k_{B} is Boltzmann's constant, Tₙ is a bin temperature, and T_{R} is a reference temperature.

The method further preferably includes, after each of the regular intervals, resetting the values stored in the second memory. The first memory preferably is a non-volatile memory, and the second memory preferably is a volatile memory. The first memory preferably is an EEPROM.

The above and other features, elements, characteristics, steps, and advantages of the present invention will become more apparent from the following detailed description of preferred embodiments of the present invention with reference to the attached drawings.

### BRIEF DESCRIPTION OF THE DRAWINGS

FIG. 1 is a flowchart according to a preferred embodiment of the present invention.

FIG. 2 is an exploded view of an AOC.

FIG. 3 is an exploded view of the printed circuit board and a molded optical structure that can be used with the AOC shown in FIG. 2.

FIG. 4 is a back perspective view of the printed circuit board shown in FIG. 3.

FIG. 5 is a front perspective view of another AOC.

FIG. 6 is an exploded view of the AOC shown in FIG. 5.

FIG. 7 is an exploded view of the printed circuit board and the molded optical structure shown in FIG. 6.

### DETAILED DESCRIPTION OF PREFERRED EMBODIMENTS

It is desirable to know how much life is remaining for an active device so that the active device or a system which incorporates the active device can be proactively replaced before it fails. A passive mechanism and/or method is needed to determine failure probability based on the operating environment of the active device. Thus, preferred embodiments of the present invention:
1) store information concerning operational parameter(s) of the active device at regular intervals, where the operational parameter(s) are monitored and recorded at regular subintervals shorter than the regular intervals; and
2) determine the active device's effective age from the stored information.

Specific examples of various preferred embodiments of the present invention provide a method of measuring and recording temperature of an active device using memory with limited ability to be written to and with limited capacity, and provide a lifetime-approximation method using the temperature data to approximate the effective age, and thus the remaining expected lifetime of the active device. The remaining expected lifetime can be used to proactively replace the active device or the system which contains the active device, i.e. an AOC, prior to failure.

Storing time-spent-at-temperature data and using a suitable lifetime-approximation method to approximate the age of the active device has several benefits. First, the lifetime-approximation method can be tailored based on the application. Second, updated lifetime approximation can be calculated as new reliability data becomes available. Third, additional onboard computing power can be reduced compared to that would otherwise be required if the calculation of the approximate age were performed by the system processor.

The age, and thus the remaining lifetime, of an active device can be estimated by knowing the approximate rate at which an active device, such as a VCSEL, ages as a function of temperature and by knowing the amount of time the active device has spent at each temperature. Active-device manufactures typically provide a relationship, i.e., a function, between the rate of aging and the active device's temperature. An active device's temperature can be measured by a sensor located in the vicinity of the active device and recorded at any time so long as the active device is powered on. Using a temperature sensor allows the active device's lifetime to be passively approximated without needing additional circuits. A suitable lifetime-approximation method can be used to determine the effective age of the active device relative to an active device operating at a constant reference temperature, which could be 40° C., for example.

The methods and apparatuses described previously regarding operational temperature can be applied to other factors that influence lifetime of an active device. A similar age estimate that takes into account other conditions that stress the device, including humidity, temperature cycling, operating current, etc., would require the ability to measure the amount of time spent at each stressed condition. For example, for an active device that ages faster at high currents, the current or power dissipation of the active device could be monitored over time to estimate device age.

Although a VCSEL is the active device used in the specific examples of the preferred embodiments of the present invention, the present invention can be applied to other active devices. For example, an AOC typically includes many types of active devices, such as, but not limited to, transimpedance amplifiers, photodetectors, laser drivers, optical sources other than VCSELs, etc. The preferred embodiments of the present invention are also applicable to any of these active devices. The VCSEL is preferably used in the preferred embodiments of the present invention because the VCSEL is expected to be the first device to fail; however, if another active device is expected to fail first, then the first-to-fail active device is preferably used. The VCSEL's age can be approximated without directly monitoring the optical output of the VCSEL, which would require additional components. Instead, the VCSEL's temperature can be passively monitored.

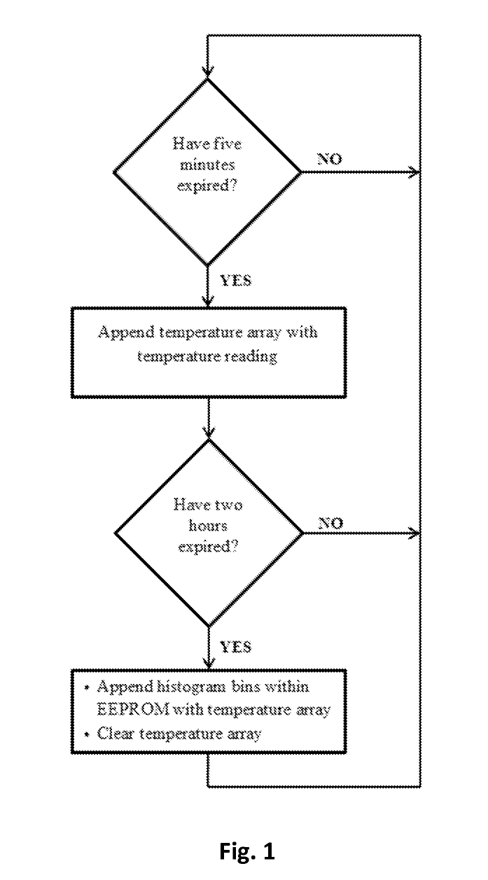

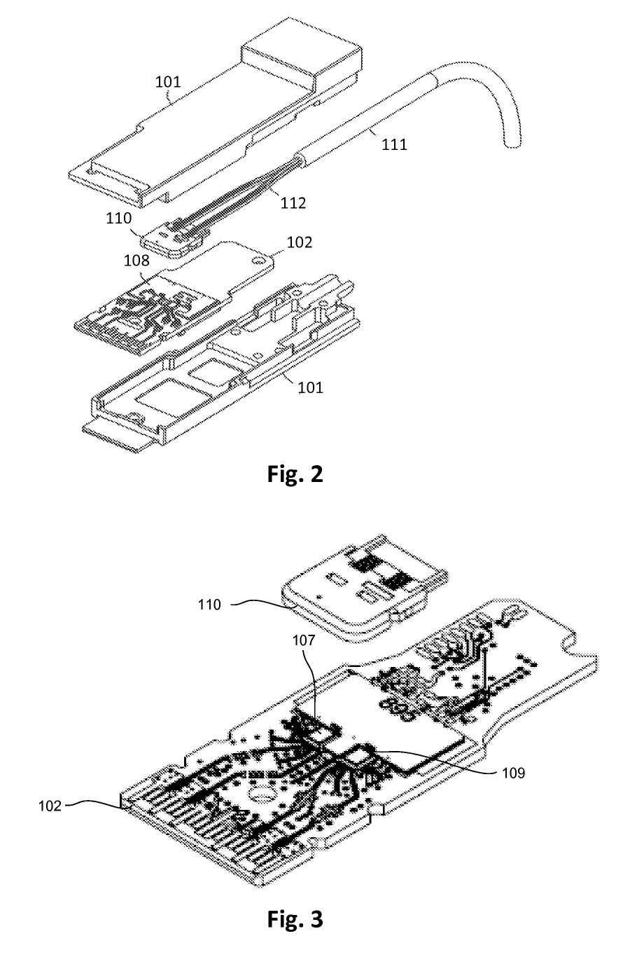

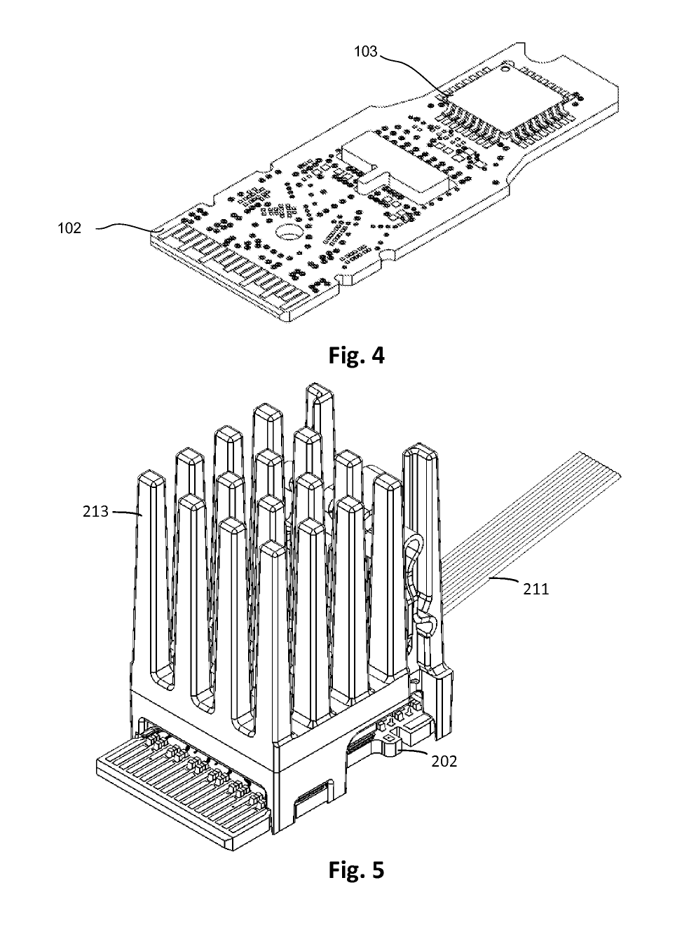

FIG. 2 is an exploded view of an AOC. FIG. 2 in this application is the same as FIG. 1 in application Ser. Nos. 12/944,545 and 12/944,562, the entire contents of which are hereby incorporated by reference. The AOC includes a housing 101, an optical cable 111 with optical fibers 112, a substrate 102, a molded optical structure (MOS) 110 that couples or connects to the substrate 102 and to the optical fibers 112, and an optical riser 108. The substrate 102 includes a photodetector 107, a VCSEL 109, and a microprocessor 103. FIG. 3 is an exploded view of the substrate 102 and the MOS 110 that can be used with the AOC shown in FIG. 2. FIG. 4 shows the back of the substrate 102 shown in FIG. 3. FIG. 3 shows the VCSEL 109 underneath the MOS 110. FIG. 4 shows the microprocessor 103 on the back of the substrate 102 that preferably includes both non-volatile memory (i.e., the EEPROM) and volatile memory. The substrate 102 also includes a temperature sensor that can be used to determine the temperature of the VCSEL 109. The temperature sensor can be an independent component or can be integrated into other components on the printed circuit board or located somewhere else in the AOC in the vicinity of the VCSEL 109. Multiple functionality is preferably incorporated into a single semiconductor chip. For example, the microprocessor, sensor, volatile memory, non-volatile memory, and VCSEL driver can be incorporated into a single application specific integrated circuit (ASIC).

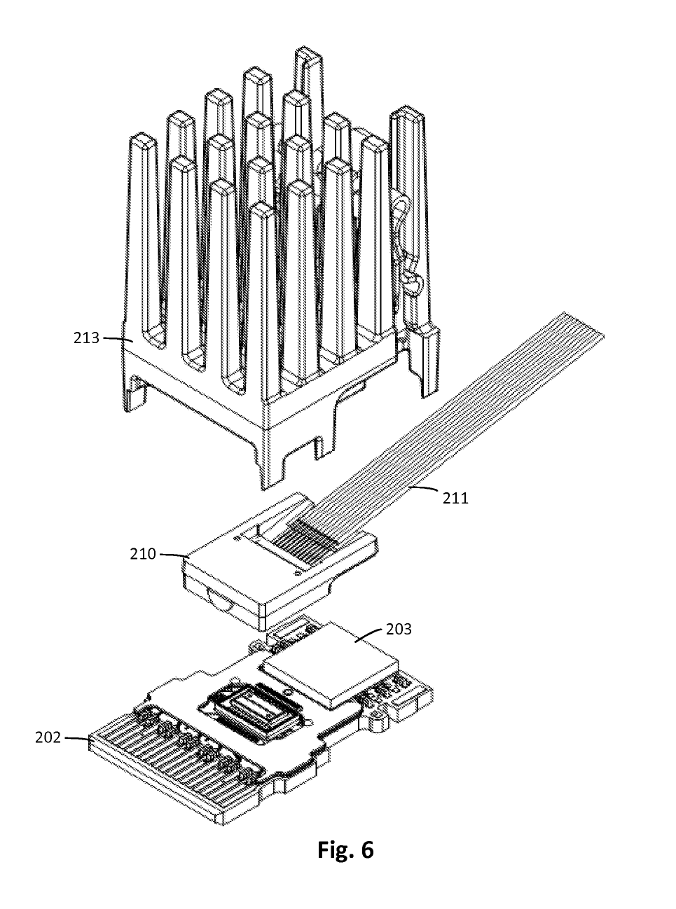

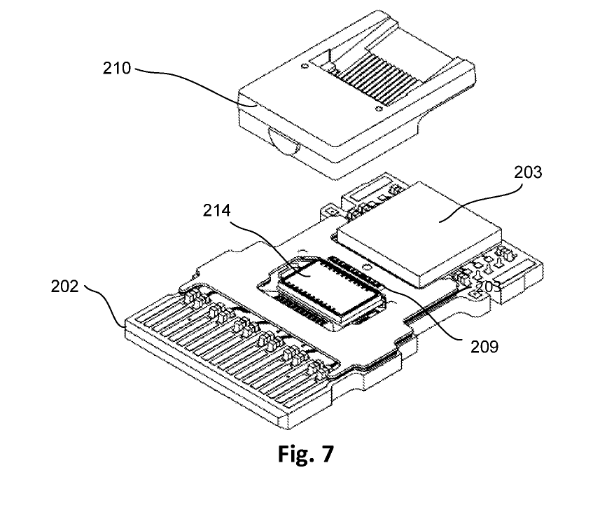

FIG. 5 shows an optical receiver that can be used in an AOC. This receiver is similar to one of the optical transceivers shown in U.S. application Ser. Nos. 13/539,173, 13/758,464, 13/895,571, 13/950,628, and 14/295,367, the entire contents of which are hereby incorporated by reference. For example, the receiver in FIGS. 5-7 in this application is similar to the optical transceiver shown in FIGS. 15A-17B of U.S. application Ser. No. 13/539,173. The receiver includes an optical cable 211, a substrate 202, a MOS 210 that couples or connects to the substrate 202 and to the optical fibers 212, a microprocessor 203, and an optional heatsink 213. The substrate 202 includes a driver 214, a VCSEL 209, and a microprocessor 203. FIG. 6 is an exploded view of the receiver shown in FIG. 5. FIG. 7 is an exploded view of the substrate 202 and the MOS 210 shown in FIG. 6. FIG. 7 shows the VCSEL 209 and the microprocessor 203 underneath the MOS 210. As with the microprocessor 103 shown in FIG. 4, the microprocessor 203 shown in FIG. 7 preferably includes both non-volatile memory (i.e., an EEPROM) and volatile memory.

Although an EEPROM is used as the memory device in the specific examples of the preferred embodiments of the present invention, the preferred embodiments of the present invention are also applicable to other suitable types of memory. Any static memory, for example, SRAM, can be used. It is also possible to use volatile memory instead of the non-volatile memory if it is possible to preserve data in the volatile memory when the active device is shut down.

### Temperature Binning

A temperature binning method according to a preferred embodiment of the present invention can be used with a memory, such as EEPROM, that has a limited ability to be written to and that has a limited capacity. Because there is not typically enough space in an EEPROM to record the exact temperature readings, the temperature values must be “binned” where each bin represents a different temperature range. The temperature binning method is used to create a temperature histogram that can be used to estimate the age of the active device. A suitable lifetime-approximation algorithm is then be applied to the temperature histogram to determine the effective age of the active device, which allows the remaining lifetime of the active device to be approximated.

The temperature histogram is divided into temperature bins, with each bin representing a different temperature range. For example, each temperature bin can represent a temperature range of 5° C. How full each temperature bin is provides a representation of the amount of time spent at that temperature range. For example, if the temperature bin for 25° C.-30° C. is more full than the temperature bin for 35° C.-40° C., then the active device has spent more time in the temperature range 25° C.-30° C. than the temperature range 35° C.-40° C.

Each temperature bin can be a certain number of bytes, e.g. three bytes, in the EEPROM. The number of bytes is chosen depending on the maximum value of a single bin. For example, in this example, three bytes was chosen because the maximum bin value needs to be approximately 1 million. If the active device remains at a constant temperature for five years, then the maximum value of the bin for that temperature will need to be larger than 525,600 because there are 525,600 possible subintervals in a 5 year period (24 [subintervals/2-hour period]×12 [2-hour period/day]×365 [days/year]×5 [years]=525,600 subintervals). Before the active device is turned on by the end user for the first time, each temperature bin will be set to zero, i.e. each byte will be set to zero, which indicates that the active device has spent no time in each temperature range. When the temperature is measured to be within a certain temperature range, then bytes for the temperature bin corresponding to that temperature range can be incremented by the proper amount.

The time interval between writing to the EEPROM, i.e., the memory-writing interval, depends on the desired lifetime of the active device and how many times that the EEPROM can be written to. For example, any given cell in the EEPROM in the particular chip selected can be written to about 30,000 times when operating at 85° C. before the cell may fail. This means that the number of writes to each temperature bin should be less than 30,000 writes if the EEPROM is expected to operate at 85° C. over its lifetime. The number of lifetime writes decreases with increasing operating temperature. For example, the number of lifetime writes could be less than 30,000 if the operating temperature of the EEPROM exceeds 85° C. The time interval is chosen such that the operating lifetime of the EEPROM exceeds that of the VCSEL (or any active device being monitored) by some safety factor. This ensures that the EEPROM can continue to record operating information on the VCSEL over its entire operating life. The appropriate safety factor to use is application specific, but is generally in the range of 1.2 to 10, for example.

If lifetime of the active device is expected to be about five years, then it is required to also have the EEPROM operate for at least as long as the VCSEL, so that the overall system device is not limited by the EEPROM. To ensure that the EEPROM can operate for five years at an operating temperature of 85° C. or less, the EEPROM should be written to every two hours (2 hours×30,000=60,000 hours≈6.8 years), assuming worst-case operating conditions. It is likely that the EEPROM's lifetime will exceed five years because (1) the active device will not be operating at the same temperature for the lifetime of the active device such that more than one temperature bin is updated and/or (2) the active device will not be operating at the maximum operating temperature for the lifetime of the active device such that the EEPROM will be capable of performing more write cycles, assuming that the EEPROM lifetime exceeds the VCSEL lifetime over the entire temperature range. This 2-hour memory-writing interval is only an example of a possible time interval. For example, if the number of writes to an EEPROM increases, then the memory-writing interval can be reduced, or if lifetime of the active device is expected be longer, then the memory-writing interval can be increased. The memory-writing interval is preferably chosen to ensure that the EEPROM life is longer than that of the VCSEL.

Because the temperature can fluctuate considerably within the memory-writing interval, e.g. 2 hours, higher granularity in temperature recording is preferred. To increase the granularity of the temperature recording, the temperature can be measured and recorded in volatile memory at a much smaller time interval, e.g. every 5 minutes. That is, the memory-writing interval can be broken down into subintervals. The temperature histogram cannot be stored in the volatile memory because all data stored in the volatile memory is lost if the active device is shut off. The volatile memory can be included in the microprocessor, which is part of the system containing the active device. For example, if the subintervals are 5 minutes and if the memory-writing time interval is two hours, then there are 24 temperature measurements that are appended to their respective temperature bins when writing to the EEPROM.

An example of the temperature binning method according to a preferred embodiment of the present invention is provided in Tables A and B. In this example, the memory-writing interval is 2 hours and the subinterval is 5 minutes. Table A shows the EEPROM with a histogram of an active device that has never been powered so that the all of the bytes for all of the temperature bins are zero, and Table B shows the EEPROM with the histogram of an active device that has been powered on for two hours. If the active device operates at 13° C. for the first memory-writing interval, then Bin #4 for the temperature range 10° C. T<15° C. will be incremented by 24 (Hex 18) to indicate that the active device spent all 24 five-minute subintervals operating between 10° C. and 15° C. as shown in Table B. A flow chart that shows the temperature binning method is shown in FIG. 1.

TABLE A
(0 hours)

| | Byte #1 | Byte #2 | Byte #3 | |
|---|---|---|---|---|
| Bin #1 | 0x00 | 0x00 | 0x00 | T < 0 ° C. |
| Bin #2 | 0x00 | 0x00 | 0x00 | 0° C. ≦ T < 5° C. |
| Bin #3 | 0x00 | 0x00 | 0x00 | 5° C. ≦ T < 10° C. |
| Bin #4 | 0x00 | 0x00 | 0x00 | 10° C. ≦ T < 15° C. |
| . . . | . . . | . . . | . . . | . . . |
| Bin #22 | 0x00 | 0x00 | 0x00 | T > 100° C. |

TABLE B
(2 hours)

| | Byte #1 | Byte #2 | Byte #3 | |
|---|---|---|---|---|
| Bin #1 | 0x00 | 0x00 | 0x00 | T < 0 ° C. |
| Bin #2 | 0x00 | 0x00 | 0x00 | 0° C. ≦ T < 5° C. |
| Bin #3 | 0x00 | 0x00 | 0x00 | 5° C. ≦ T < 10° C. |
| Bin #4 | 0x00 | 0x00 | 0x18 | 10° C. ≦ T < 15° C. |
| . . . | . . . | . . . | . . . | . . . |
| Bin #22 | 0x00 | 0x00 | 0x00 | T > 100° C. |

The histogram is updated after the next two hours, for example, with each temperature bin being incremented by one for each 5-minute subinterval, that the active device is measured within that temperature range. At any time, the temperature histogram indicates the amount of time in five-minute subintervals spent at each temperature range. The temperature histogram can then be used to approximate the effective age of the active device.

The temperature bins could be larger or smaller than three bytes, for example. The number of bins can be larger or smaller than 22, for example. The temperature range can be larger or smaller than 5° C., for example. Any suitable coding scheme, including big endian or little endian, can be used to store the size of the temperature bin.

The memory-writing interval, the subinterval, and the bin sizes can be optimized based on the thermal time constant of the active device, the anticipated active device lifetime, and the EEPROM's lifetime and capacity. For example, if thermal time constant of the active device is large so that the temperature of the active device changes slowly, then the memory-writing interval and the subinterval can be increased and the temperature bin size can be decreased. Active devices with long anticipated lifetimes can use longer memory-writing intervals and subintervals. High capacity EEPROM's can support larger bin sizes. The lifetime of 5 years, the memory-writing interval of 2 hours, and the subinterval of 5 minutes used above are examples only and can be appropriately changed and optimized for various applications.

### Lifetime-Approximation Algorithm

An example of the lifetime-approximation method is the Arrhenius equation, which is an empirical formula that can be used to approximate the temperature dependence of chemical reactions. It is also used in reliability calculations as a method to determine the impact of accelerated aging when operating at high temperatures. That is, the Arrhenius equation can be used to determine the effective age-acceleration factor of an active device relative to an active device operating at a constant 40° C. or some other reference temperature. The Arrhenius equation is provided in Equation 1, where k is the rate constant, A is a proportionality constant, E_{A} is the activation energy, k_{B} is Boltzmann's constant, and T is the temperature in Kelvin.

$$Arrhenius Equation \\ k = A {e}^{( - {E}_{A} / {k}_{B} T )} \qquad Equation 1$$

The activation energy E_{A} is typically provided in a reliability study by the active device's manufacturer.

The age-acceleration factor A_{F}, which is defined as the rate at which aging is accelerated at high temperature operation compared to operation at a reference temperature, is provided by Equation 2, where t_{H} is the high temperature and t_{R} is the lower, reference temperature

$$Age \text{-} acceleration factor \\ {A}_{F} = \frac{{t}_{H}}{{t}_{R}} \qquad Equation 2$$

The age-acceleration factor A_{F} is related to the Arrhenius equation through t_{H} and t_{R} which are equivalent to the rate constants determined in the Arrhenius equation at their respective temperature levels. The method that is used to approximate the effective age of the active device relies on determining the age-acceleration factor A_{F} for each temperature bin Tₙ relative to a reference temperature T_{R}, which can be found from Equation 3, where n is the bin number:

$$Age \text{-} acceleration factor for the {n}^{th} temperature bin \\ {A}_{Fn} = {e}^{[ \frac{- {E}_{A}}{{k}_{B}} ( \frac{1}{{T}_{n}} - \frac{1}{{T}_{R}} ) ]} \qquad Equation 3$$

The temperature bin Tₙ can be chosen to be any temperature in bin range of temperatures, including, for example, the lowest temperature in the bin range, the average temperature in the bin range, and the highest temperature in the bin range.

The effective age t_{effective} of the active device in hours is then found by taking the product of the time spent Nₙ at each temperature and the corresponding age-acceleration factor A_{Fn} for that temperature and summing these values for all the bins. The equation for the approximate effective age t_{effective} is given by, where Nₙ is the value stored in bin n and the subinterval time is assumed to be 5 minutes:

$$Effective age of the device \\ {t}_{effective} = \frac{1}{12} {\sum }_{n = 1}^{22} {A}_{Fn} {N}_{n} [ hours ] \qquad Equation 4$$

This equation can be generalized to accommodate a system that takes temperature readings every m minutes and bins the readings into b bins:

$$General equation for approximating device age \\ {t}_{effective} = \frac{m}{60} {\sum }_{n = 1}^{b} {A}_{Fn} {N}_{n} [ hours ] \qquad Equation 5$$

Once the effective age t_{effective} has been approximated, then it is possible to approximate the remaining lifetime of the active device by subtracting the effective age t_{effective} from the MTTF of the active device. Comparison of the effective age t_{effective} with other metrics of device lifetime can also be made. For example, the effective age t_{effective} can be compared with B10, B5 or B1 life, which represent the time to failure of 10%, 5% or 1% of the population, respectively. In certain applications it may be appropriate to replace the system once the active device effective age reaches one of these lifetime metrics. Other lifetime metrics, other than those explicitly described, can also be used.

Determination of the effective age, t_{effective}, and remaining lifetime can be performed in various manners and locations. In a preferred embodiment of the present invention, the microprocessor shown in FIG. 4 can communicate with the non-volatile memory, interrogate the various memory bins, and perform the calculations necessary to determine the effective age t_{effective}. The microprocessor can send an indicator signal to a user once the effective age t_{effective} exceeds some threshold. In another preferred embodiment of the present invention, an external device, not part of the system including the active device, can communicate with the non-volatile memory, interrogate the various memory bins and perform the calculations necessary to determine the effective age t_{effective}. The external device can provide an indicator signal to a user once the effective age t_{effective} exceeds some threshold.

The effective age t_{effective} can be approximated using any other aging model, including models that are modifications of the Arrhenius-based models and models that are not derived from the Arrhenius equation. The effective age t_{effective} can be determined based on any measurable condition that affects the active device's age. Measurable conditions include, for example, humidity, temperature cycling, current, power dissipation, UV exposure, etc. For example, the models disclosed in Rodriguez, Parametric Survival Models, Summer 2010, 14 pages, which is incorporated in its entirety, could be used. The effective age t_{effective} can be based on temperature in combination with any other measurable condition or can be based on any measurable condition or conditions without considering temperature.

In some applications, a fixed bias current is applied to the laser over the lifetime of the active device. An age-acceleration factor based on the bias current can be used to calculate the effective age of the active device. Both a bias-current-based age-acceleration factor and a temperature-based age-acceleration factor, e.g. A_{Fn} in Equation 3, can be used to determine the effective age of the active device.

In other applications, a variable bias current is applied to the laser over the lifetime of the active device. For example, the optical output power of a semiconductor laser generally drops with temperature. In some applications, it is desirable to maintain a relatively constant optical output power with temperature. In such applications, increasing the bias current applied to the laser as the temperature increases can be used to maintain a relatively constant optical output power. Because operating at an increased bias current generally increases the age-acceleration factor in a known manner, each temperature bin has an associated bias-current-based age-acceleration factor. Both a bias-current-based age-acceleration factor and a temperature-based age-acceleration factor, e.g., A_{Fn} in Equation 3, can be used to determine the effective age of the active device. The total age-acceleration factor can be determined for each temperature bin, for example, by multiplying the right side of Equation 3 by the bias-current-based age-acceleration factor associated with each temperature bin.

The specific examples of the preferred embodiments of the present invention consider temperature because it is the measurable condition that most affects the age of the VCSEL; however, it is possible that measurable conditions other than temperature might have more of an effect on aging for other active devices.

It should be understood that the foregoing description is only illustrative of the present invention. While the preferred embodiments of the present invention have been described in terms of the active device being a VCSEL, the system being an AOC, and the measured operating parameter being temperature, these are only specific examples of the preferred embodiments of the present invention. The preferred embodiments of the present invention can be applied to any system having an active device whose lifetime depends on some measurable operational parameter. In some embodiments, more than one operational parameter can be measured and recorded and the effective age calculated based on the combined effects of these two parameters. Various alternatives and modifications can be devised by those skilled in the art without departing from the present invention. Accordingly, the present invention is intended to embrace all such alternatives, modifications, and variances that fall within the scope of the appended claims.

What is claimed is:

1. An active optical cable comprising:
a fiber optic cable;
at least one optical transducer;
a first memory;
a second memory;
a sensor that senses an operational parameter of the active optical cable; and
a processor connected to the least one optical transducer, the first memory, the second memory, and the sensor; wherein
the processor:
during regular intervals that are divided into regular subintervals and after each of the regular subintervals, records in the second memory a value corresponding to a sensed operational parameter; and
after each of the regular intervals, stores in the first memory the values recorded in the second memory.

2. An active optical cable of claim 1, wherein the regular intervals and the regular subintervals are based on an expected number of writes to the first memory and an expected lifetime of the active optical cable.

3. An active optical cable of claim 1, wherein the operational parameter is temperature.

4. An active optical cable of claim 1, wherein:
the second memory includes bins; and
each of the bins corresponds to a range of values of the sensed operational parameter.

5. An active optical cable of claim 4, wherein the processor records in the second memory the value corresponding to the sensed operational parameter by incrementing by one a bin value of a bin that corresponds to the range of values of the sensed operational parameter that includes the value of the sensed operational parameter.

6. An active optical cable of claim 5, wherein the first memory includes bins corresponding to the bins in the second memory.

7. An active optical cable of claim 6, wherein the processor stores in the first memory the values recorded in the second memory by adding a bin value of each of the bins in the second memory to a corresponding bin value previously stored in corresponding bins in the first memory.

8. An active optical cable of claim 7, wherein the processor calculates an effective age of the active optical cable based on the bin values of the bins stored in the first memory.

9. An active optical cable of claim 8, wherein the processor calculates the effective age based solely on the bin values of the bins stored in the first memory.

10. An active optical cable of claim 8, wherein the processor provides an indicator signal if the effective age is above a threshold value.

11. An active optical cable of claim 7, wherein:
the operational parameter is temperature, and each of the bins represents a range of temperatures; and
the processor calculates an effective age of the active optical cable t_{effective} using a formula:
$${t}_{effective} = \frac{m}{60} {\sum }_{n = 1}^{b} {A}_{Fn} {N}_{n} [ hours ]$$
$$where$$
$${A}_{Fn} = {e}^{[ \frac{- {E}_{A}}{{k}_{B}} ( \frac{1}{{T}_{n}} - \frac{1}{{T}_{R}} ) ]} ,$$
m is a time of a regular subinterval in minutes, b is a number of bins, Nₙ is a value stored in bin n, E_{A} is an activation energy, k_{B} is Boltzmann's constant, Tₙ is a bin temperature, and T_{R} is a reference temperature.

12. An active optical cable of claim 1, wherein, after each of the regular intervals, the processor resets the values stored in the second memory.

13. An active optical cable of claim 1, wherein the processor calculates an effective age of the active optical cable based on the values stored in the first memory.

14. An active optical cable of claim 1, wherein the first memory is a non-volatile memory and the second memory is a volatile memory.

15. An active optical cable of claim 1, wherein the first memory is an EEPROM.

16. A method of calculating an effective age of an active optical cable including a fiber optic cable, at least one optical transducer, a first memory, and a second memory, the method comprising:
during regular intervals that are divided into regular subintervals and after each of the regular subintervals, sensing an operational parameter of the active optical cable and recording in the second memory a value corresponding to a sensed operational parameter;
after each of the regular intervals, storing in the first memory the values recorded in the second memory; and
calculating the effective age of the active optical cable based on the values stored in the first memory.

17. A method of claim 16, wherein the regular intervals and the regular subintervals are based on an expected number of writes to the first memory and an expected lifetime of the active optical cable.

18. A method of claim 16, wherein the operational parameter is temperature.

19. A method of claim 16, wherein:
the second memory includes bins; and
each of the bins corresponds to a range of values of the sensed operational parameter.

20. A method of claim 19, wherein the recording in the second memory the value corresponding to the sensed operational parameter includes incrementing by one a bin value of a bin that corresponds to the range of values of the sensed operational parameter that includes the value of the sensed operational parameter.

21. A method of claim 20, wherein the first memory includes bins corresponding to the bins in the second memory.

22. A method of claim 21, wherein the storing in the first memory the values recorded in the second memory includes adding a bin value of each of the bins in the second memory to a corresponding bin value previously stored in corresponding bins in the first memory.

23. A method of claim 22, wherein calculating the effective age of the active optical cable is based on the bin values of the bins stored in the first memory.

24. A method of claim 23, wherein calculating the effective age is based solely on the bin values of the bins stored in the first memory.

25. A method of claim 23, further comprising providing an indicator signal if the effective age is above a threshold value.

26. A method of claim 22, wherein:
the operational parameter is temperature, and each of the bins represents a range of temperatures; and
the calculating the effective age of the active optical cable includes using a formula:
$${t}_{effective} = \frac{m}{60} {\sum }_{n = 1}^{b} {A}_{Fn} {N}_{n} [ hours ]$$
$$where$$
$${A}_{Fn} = {e}^{[ \frac{- {E}_{A}}{{k}_{B}} ( \frac{1}{{T}_{n}} - \frac{1}{{T}_{R}} ) ]} ,$$
t_{effective} is an effective age of the active optical cable, m is a time of a regular subinterval in minutes, b is a number of bins, Nₙ is a value stored in bin n, E_{A} is an activation energy, k_{B} is Boltzmann's constant, Tₙ is a bin temperature, and T_{R} is a reference temperature.

27. A method of claim 16, further comprising, after each of the regular intervals, resetting the values stored in the second memory.

28. A method of claim 16, wherein the first memory is a non-volatile memory and the second memory is a volatile memory.

29. A method of claim 16, wherein the first memory is an EEPROM.
